(19) United States
(12) Patent Application Publication
(10) Pub. No.: US 2012/0162189 A1
(43) Pub. Date: Jun. 28, 2012

(54) DRIVER CIRCUIT AND VIDEO SYSTEM

(75) Inventors: Tsuyoshi Ebuchi, Osaka (JP); Yoshihide Komatsu, Osaka (JP); Kurumi Nakayama, Osaka (JP)

(73) Assignee: Panasonic Corporation, Osaka (JP)

(21) Appl. No.: 13/412,258

(22) Filed: Mar. 5, 2012

Related U.S. Application Data
(63) Continuation of application No. PCT/JP2010/004420, filed on Jul. 6, 2010.

(30) Foreign Application Priority Data
Sep. 18, 2009 (JP) 2009-216523

(51) Int. Cl. G09G 5/00; H03K 3/00

(52) U.S. Cl. 345/212; 327/108

(57) ABSTRACT

In a driver circuit in a transmission system, an output circuit outputs a differential signal based on input data signals. A current source control circuit controls a constant current source so that a common-mode potential of the differential signal becomes equal to a predetermined reference potential. An overshoot reduction circuit is connected to an input line of the common-mode potential of the current source control circuit, and reduces an overshoot of the common-mode potential based on the control signal.

### CROSS-REFERENCE TO RELATED APPLICATIONS

This is a continuation of PCT International Application PCT/JP2010/004420 filed on Jul. 6, 2010, which claims priority to Japanese Patent Application No. 2009-216523 filed on Sep. 18, 2009. The disclosures of these applications including the specifications, the drawings, and the claims are hereby incorporated by reference in their entirety.

### BACKGROUND

The present disclosure relates to driver circuits for use in data transmission systems, and more particularly, to techniques of reducing an overshoot of an output voltage.

Low voltage differential signaling (LVDS) is used as an interface for data transmission between each image processing LSI circuit or between an image processing LSI circuit and a display driver in a digital television. There are a number of standards for LVDS, including IEEE Standard 1596.3-1996, mini-LVDS, sub-LVDS, etc. A driver circuit may be connected to various receiver circuits.

FIG. 9 is a diagram schematically showing a typical LVDS data transmission system. The system of FIG. 9 includes a transmitter LSI circuit having a current driver circuit DRV, a transmission path (a cable or a printed circuit board (PCB)), a terminating resistor RT (e.g., 100Ω), and a receiver LSI circuit having a receiver circuit REC. Amplitude is produced by the current driver circuit DRV causing a current to flow into the terminating resistor RT, and is then amplified by the receiver circuit REC, whereby a signal is transmitted. The voltage level (common-mode potential) of the signal is normally determined by the current driver circuit DRV. The common-mode potential is typically 1.25 V.

Japanese Patent Publication Nos. 2005-109897 and 2008-199236 describe example configurations of the LVDS driver circuit. For example, FIG. 10 shows a configuration of a driver circuit described in Japanese Patent Publication No. 2008-199236, in which a resistor switch circuit 53 is provided between a differential circuit 52 and the ground. A controller 54 switches off a switch SW of the resistor switch circuit 53 in the sleep mode so that a common-mode voltage Vcom is maintained at the same level as that in the normal mode.

### SUMMARY

In the system of FIG. 9, the transmitter LSI circuit and the receiver LSI circuit are often manufactured by different manufacturers. In this case, the transmitter LSI circuit and the receiver LSI circuit are manufactured by different manufacturing processes. Therefore, in most cases, the transmitter LSI circuit and the receiver LSI circuit have different power supply voltages.

For example, it is assumed that a power supply voltage VDDT for the transmitter LSI circuit is 3.3 V, a power supply voltage VDDR for the receiver LSI circuit is 1.8 V, and the process breakdown voltage of the receiver LSI circuit is 2.5 V. In this case, if a signal exceeding the process breakdown voltage (2.5 V) of the receiver LSI circuit is transmitted from the transmitter LSI circuit to the receiver LSI circuit, the receiver LSI circuit may be damaged. Because the common-mode potential is 1.25 V, a problem does not particularly arise during normal operation. However, in a transient state (e.g., when the power supply rises, etc.), an overshoot occurs in the output voltage of the driver circuit, likely leading to a problem.

In particular, if the driver circuit employs a feedback configuration in order to stabilize the common-mode potential, the overshoot problem becomes more significant.

The present disclosure describes implementations of a driver circuit for use in a transmission system which reliably establishes connection to a receiver circuit having a different power supply voltage or process breakdown voltage by reducing an overshoot of an output voltage during the start of operation etc.

An example driver circuit according to the present disclosure includes an output circuit configured to receive a data signal, and output a differential signal based on the data signal, a constant current source configured to supply a constant current to the output circuit, or extract a constant current from the output circuit, a current source control circuit configured to receive a predetermined reference voltage and a common-mode potential of the differential signal, and control the constant current source so that the common-mode potential becomes equal to the predetermined reference potential, and an overshoot reduction circuit connected to an input line of the common-mode potential of the current source control circuit, and having a function to reduce an overshoot of the common-mode potential. The overshoot reduction circuit receives a control signal to select whether or not to perform the overshoot reduction operation, and when selecting, based on the control signal, to perform the overshoot reduction operation, reduces the overshoot of the common-mode potential.

The example driver circuit includes the overshoot reduction circuit which receives a control signal to select whether or not to perform the overshoot reduction operation, and when selecting, based on the control signal, to perform the overshoot reduction operation, reduces the overshoot of the common-mode potential. As a result, an overshoot of an output voltage during the start of operation etc. can be reduced, and therefore, the driver circuit can be reliably connected to a receiver circuit having a different power supply voltage or process breakdown voltage.

The overshoot reduction circuit, when selecting, based on the control signal, to perform the overshoot reduction operation, causes a short circuit in the input line of the reference voltage and the input line of the common-mode potential of the current source control circuit. As a result, the common-mode potential can be forcibly clamped to the reference voltage, and therefore, the common-mode potential can be directly input to the output terminal, whereby the amount of the overshoot can be minimized. Also, such a considerably simple configuration can be used to reduce or prevent the overshoot of the output voltage of the driver circuit, resulting in a low-power, small-area, and low-cost driver circuit which can reduce the overshoot.

Also, the overshoot reduction circuit, when selecting, based on the control signal, to perform the overshoot reduction operation, causes a short circuit in both ends of a resistance element provided between an output line of the common-mode potential of the output circuit and the input line of the common-mode potential of the current source control circuit. This configuration can temporarily increase a frequency characteristic of the current source control circuit, whereby the overshoot of the output voltage can be reduced. Also, the clamp voltage is not required, and such a considerably simple configuration can be used to reduce or prevent the overshoot of the output voltage of the driver circuit, resulting in a low-power, small-area, and low-cost driver circuit which can reduce the overshoot.

According to the present disclosure, the overshoot reduction circuit can reduce the overshoot of the output voltage during the start of operation etc., and therefore, it is possible to provide a driver circuit which can be connected to a receiver circuit having a different power supply voltage or process breakdown voltage.

### BRIEF DESCRIPTION OF THE DRAWINGS

FIG. 1 is a circuit diagram showing a configuration of a driver circuit according to a first embodiment.

FIG. 2 is a diagram showing an example circuit configuration of a common-mode feedback amplifier in a current source control circuit.

FIG. 3 is a diagram showing an example configuration of an overshoot reduction circuit.

FIG. 4 is a circuit diagram showing a configuration of a driver circuit according to a second embodiment.

FIG. 5 is a circuit diagram showing another configuration of the driver circuit of the second embodiment.

FIG. 6 is a timing diagram showing an example control of overshoot reduction operation.

FIG. 7 is a timing diagram showing an example control of overshoot reduction operation.

FIG. 8 is a diagram schematically showing an example configuration of a video system including the driver circuit of any of the embodiments.

FIG. 9 is a diagram schematically showing a typical LVDS data transmission system.

FIG. 10 is a diagram showing an example configuration of a conventional driver circuit.

FIG. 11 is a diagram showing an example configuration of a driver circuit employing common-mode feedback.

### DETAILED DESCRIPTION

Embodiments of the present disclosure will be described in detail hereinafter with reference to the accompanying drawings.

### First Embodiment

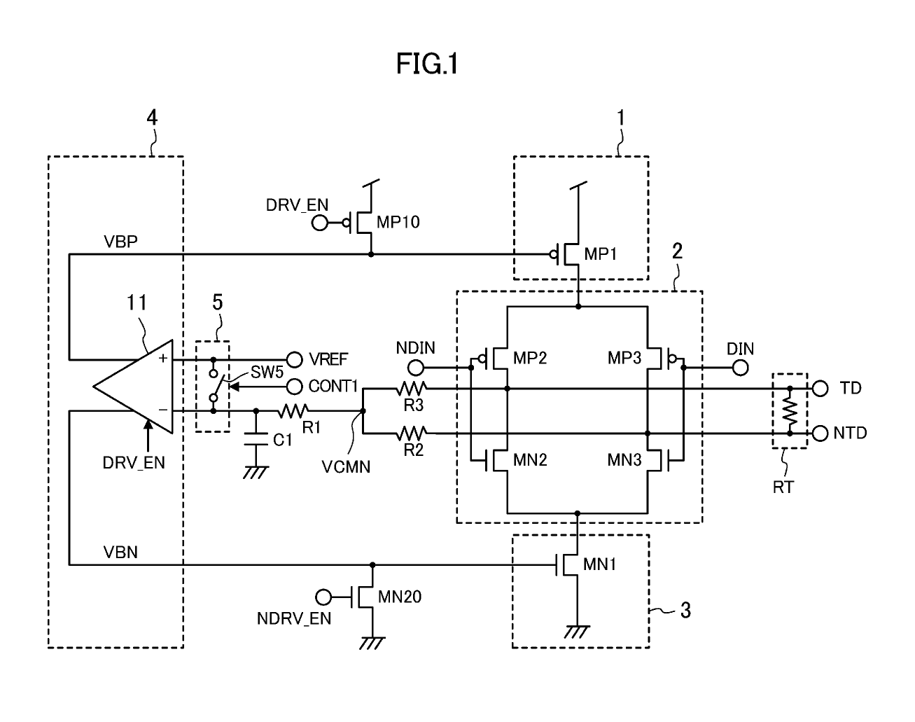

FIG. 1 is a circuit diagram showing a configuration of a driver circuit according to a first embodiment. The circuit of FIG. 1 is a differential current driver circuit which receives complementary data signals DIN and NDIN at the CMOS level, and causes a current to flow into a terminating resistor RT (typically, 100Ω) provided between output terminals TD and NTD to generate a differential signal having a small amplitude. In typical LVDS, a current of 3.5 mA is caused to flow into the terminating resistor RT to generate an amplitude of 350 mV (=3.5 mA×100Ω). Note that the terminating resistor RT may be provided outside an LSI circuit including the driver circuit or may be formed of a silicon resistor or a MOS resistor in the LSI circuit.

The driver circuit of FIG. 1 includes an output circuit 2 which receives the data signals DIN and NDIN, and outputs a differential signal based on the data signals DIN and NDIN, a constant current source 1 at the power supply side to supply a constant current to the output circuit 2, a constant current source 3 at the ground side to extract a constant current from the output circuit 2, and a current source control circuit 4 which receives a predetermined reference voltage VREF (generated by an external reference voltage circuit) for common-mode feedback and an intermediate potential (common-mode potential) VCMN of the differential signal output from the output circuit 2, and controls the constant current sources 1 and 3 so that the common-mode potential VCMN becomes equal to the reference voltage VREF.

The output circuit 2 includes PMOS transistors MP2 and MP3 and NMOS transistors MN2 and MN3. The transistors MP2 and MN2 are connected together in series, and both receive the data signal NDIN at the gates thereof. The transistors MP3 and MN3 are also connected together in series, and both receive the data signal DIN at the gates thereof. The transistors MP2 and MN2 and the transistors MP3 and MN3 are connected in parallel between the power supply and the ground. The output circuit 2 outputs the differential signal by changing the direction of a current flowing through the terminating resistor RT between the output terminals TD and NTD, depending on the polarities of the data signals DIN and NDIN. When the data is positive, the transistors MP2 and MN3 are turned on, so that a current flows in the direction of MP2→TD→NTD→MN3. Conversely, when the data is negative, the transistors MP3 and MN2 are turned on, so that a current flows in the direction of MP3→NTD→TD→MN2.

The constant current source 1 includes a PMOS transistor MP1 provided between the power supply and the output circuit 2. The constant current source 3 includes an NMOS transistor MN1 provided between the output circuit 2 and the ground. Adjustment voltages VBP and VBN output from the current source control circuit 4 are input to the gates of the transistors MP1 and MN1, respectively.

Two lines are extracted from the output terminals TD and NTD via resistors R2 and R3. The two lines are connected together as the output line of the common-mode potential VCMN. A resistance element R1 is provided between the output lines of the common-mode potential VCMN of the output circuit 2 and an input line of the common-mode potential VCMN of the current source control circuit 4. A capacitance element C1 is provided between an end closer to the current source control circuit 4 of the resistance element R1 and the ground. The resistance element R1 and the capacitance element C1 form a low-pass filter which cuts off an AC component of the common-mode potential VCMN.

The current source control circuit 4 includes a common-mode feedback amplifier (CMFBA) 11. An enable signal DRV_EN for the driver circuit is input to the common-mode feedback amplifier (CMFBA) 11. When the enable signal DRV_EN is high, the driver circuit is in an enabled state, and when the enable signal DRV_EN is low, the driver circuit is in a power-down state. An inverted version of the enable signal DRV_EN is indicated by NDRV_EN. A PMOS transistor MP10 is situated between interconnects of the adjustment voltage VBP and the power supply. The enable signal DRV_EN is input to the gate of the PMOS transistor MP10. An NMOS transistor MN20 is situated between interconnects of the adjustment voltage VBN and the ground. The inverted signal NDRV_EN is input to the gate of the NMOS transistor MN20.

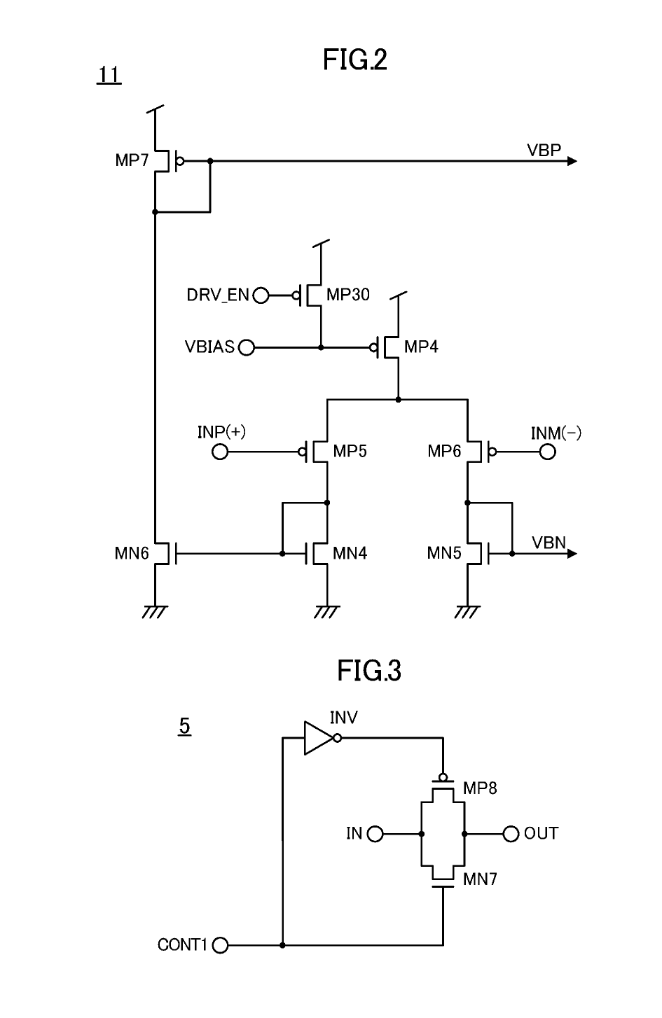

FIG. 2 is a diagram showing an example circuit configuration of the common-mode feedback amplifier 11 in the current source control circuit 4. The common-mode feedback amplifier 11 of FIG. 2 is a P-type input differential amplifier which includes PMOS transistors MP4, MP5, MP6, MP7, and MP30, and NMOS transistors MN4, MN5, and MN6. The adjustment voltages VBP and VBN are adjusted so that inputs INP and INM (to which the reference voltage VREF and the common-mode potential VCMN are input, respectively, in the configuration of FIG. 1) have the same potential. A bias voltage VBIAS for generating a constant current for the amplifier is supplied from an external reference voltage generation circuit (typically, a band gap reference circuit (BGR)).

Although FIG. 2 shows the P-type input differential amplifier as an example, the common-mode feedback amplifier 11 may be an N-type input differential amplifier if, for example, the common-mode potential VCMN is high. Alternatively, the common-mode feedback amplifier 11 may be a Rail-Rail type differential amplifier which includes both a P-type input and an N-type input and can handle all voltages between the power supply and the ground.

The configuration of FIG. 1 further includes an overshoot reduction circuit 5 which is connected to the input line of the common-mode potential VCMN of the current source control circuit 4 and has function of reducing an overshoot of the common-mode potential VCMN. The overshoot reduction circuit 5 receives a control signal CONT1 to select whether or not to perform the overshoot reduction operation, and when selecting, based on the control signal CONT1, to perform the overshoot reduction operation, reduces the overshoot of the common-mode potential VCMN. The overshoot reduction circuit 5 enables the driver circuit to connect to a receiver circuit having a different power supply voltage or process breakdown voltage.

Specifically, the overshoot reduction circuit 5 includes a switch SW5 which is provided between the input line of the reference voltage VREF and the input line of the common-mode potential VCMN of the current source control circuit 4, and based on the control signal CONT1, sets whether or not to cause a short circuit in these two input lines. When the overshoot reduction circuit 5 selects, based on the control signal CONT1, to perform the overshoot reduction operation, the switch SW5 causes a short circuit in the two input lines. By this short-circuit operation, the input line of the common-mode potential VCMN is forcibly clamped to the reference voltage VREF.

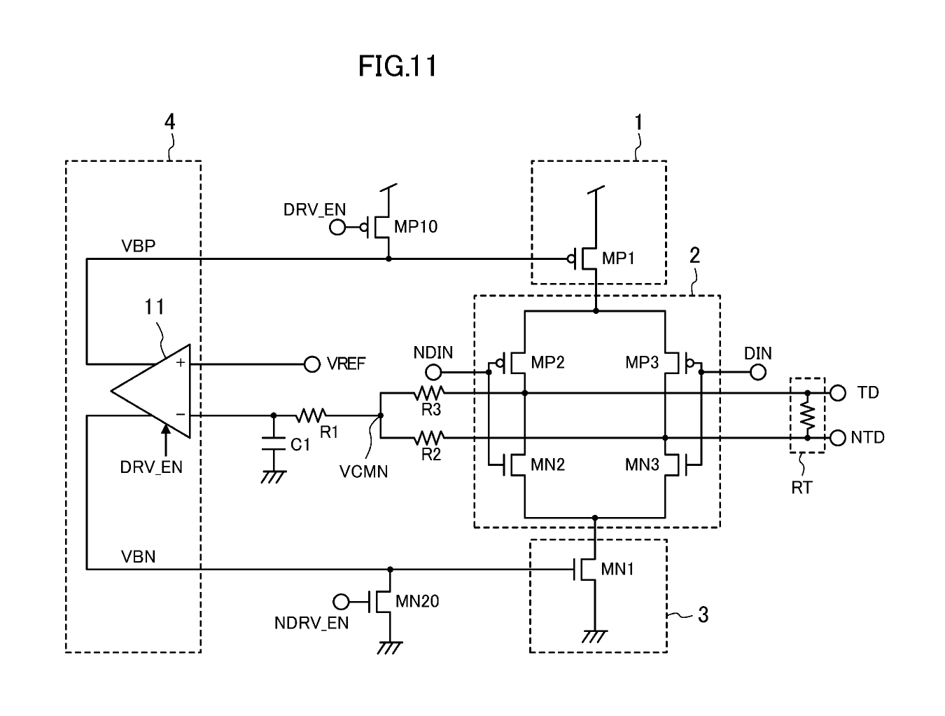

FIG. 11 is a diagram showing a comparative example configuration of a driver circuit employing common-mode feedback. Similar to FIG. 1, the configuration of FIG. 11 includes an output circuit 2 which receives data signals DIN and NDIN, and outputs a differential signal based on the data signals DIN and NDIN, a constant current source 1 at the power supply side, a constant current source 3 at the ground side, and a current source control circuit 4 which feeds back a common-mode potential VCMN. The current source control circuit 4 performs feedback operation on the constant current sources 1 and 3 so that the common-mode potential VCMN becomes equal to a reference potential VREF. For example, the current source control circuit 4 adjusts the common-mode potential VCMN to 1.25 V. Also, a resistance element R1 and a capacitance element C1 are provided to form a low-pass filter which cuts off a high frequency component of the common-mode potential VCMN.

In the configuration of FIG. 11, however, the resistance element R1 and the capacitance element C1 which have a large time constant are provided in the common-mode feedback loop, and therefore, the current source control circuit 4 has a low response characteristic. For example, an overshoot occurs due to a transient response during the start of driver operation (enabling) after the rise of the power supply. Therefore, this overshoot may cause the output voltage of the driver circuit to exceed the process breakdown voltage of a receiver LSI circuit.

In other words, the resistance element R1 and the capacitance element C1 forming the low-pass filter typically have a large value in order to reliably cut off a high frequency component of the common-mode potential VCMN. Therefore, the response characteristic of the current source control circuit 4 is reduced, and therefore, an overshoot is highly likely to occur due to a transient response during the start of operation after the power supply is turned on, for example. To solve this problem, in this embodiment, the overshoot reduction circuit 5 selects, based on the control signal CONT1, to perform the overshoot reduction operation during a period of time in which an overshoot is highly likely to occur. As a result, the overshoot reduction circuit 5 causes a short circuit in the input line of the reference voltage VREF and the input line of the common-mode potential VCMN of the current source control circuit 4. By this short-circuit operation, the common-mode potential VCMN is forcibly clamped to the reference voltage VREF, whereby the overshoot of the output voltage can be reduced or prevented.

FIG. 3 is a diagram showing an example configuration of the overshoot reduction circuit 5. In the configuration of FIG. 3, a PMOS transistor MP8 and an NMOS transistor MN7 are connected together in parallel to form a transmission gate, which functions a switch. Also, in the configuration of FIG. 3, the switch is on when the control signal CONT1 is high, and off when the control signal CONT1 is low. In other words, the overshoot reduction operation is performed when the control signal CONT1 is high, and is not performed when the control signal CONT1 is low. The configuration of FIG. 3 can be used no matter whether the input voltage is low or high. Note that, for example, when the input voltage range is limited, the switch may include only PMOS transistors or only NMOS transistors.

In this embodiment, the overshoot reduction circuit 5 is provided which receives the control signal CONT1 to select whether or not to perform the overshoot reduction operation, and when selecting, based on the control signal CONT1, to perform the overshoot reduction operation, reduces the overshoot of the common-mode potential VCMN. As a result, the driver circuit can be connected to a receiver circuit having a different power supply voltage or process breakdown voltage.

Also, the overshoot reduction circuit 5, when selecting, based on the control signal CONT1, to perform the overshoot reduction operation, causes a short circuit in the input line of the reference voltage VREF and the input line of the common-mode potential VCMN of the current source control circuit 4. With this configuration, the common-mode potential VCMN can be forcibly clamped to the reference voltage VREF, and therefore, the common-mode potential can be directly input to the output terminal, whereby the amount of the overshoot can be minimized. Also, such a considerably simple configuration can be used to reduce or prevent the overshoot of the output voltage of the driver circuit, resulting in a low-power, small-area, and low-cost driver circuit which can reduce the overshoot.

### Second Embodiment

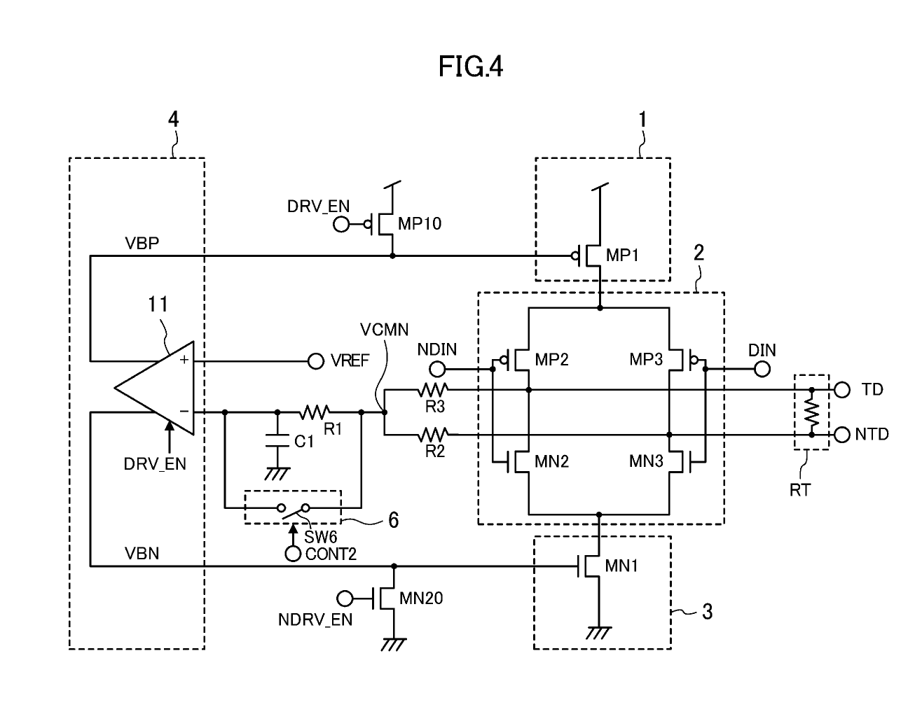

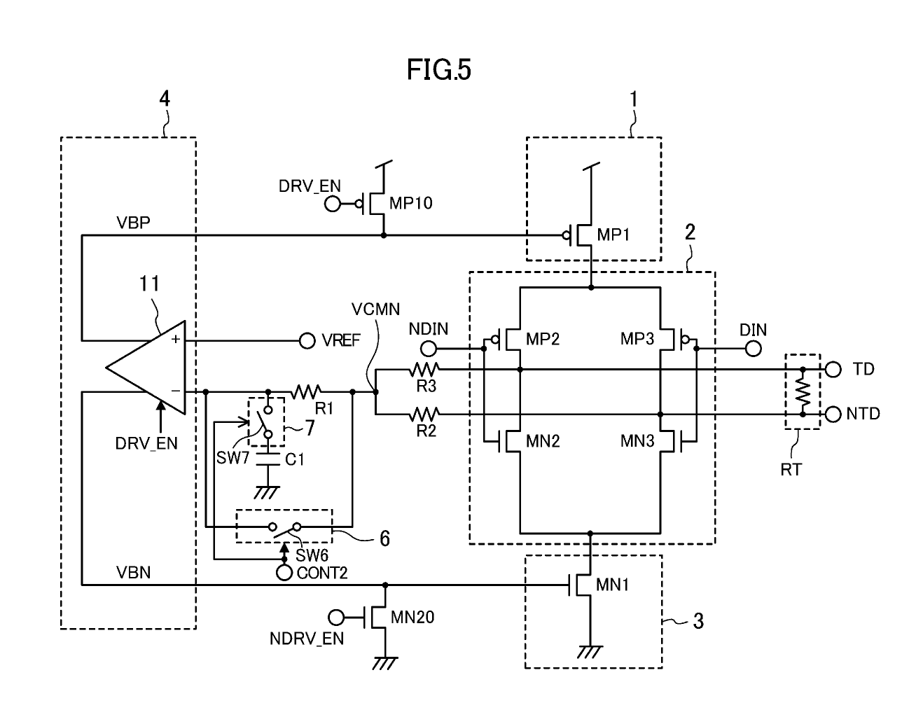

FIG. 4 is a circuit diagram showing a configuration of a driver circuit according to a second embodiment. In FIG. 4, the same parts as those of FIG. 1 are indicated by the same reference characters and will not be here described in detail.

The driver circuit of FIG. 4 includes an overshoot reduction circuit 6 having a different configuration instead of the overshoot reduction circuit 5 of FIG. 1. Similar to the overshoot reduction circuit 5 of FIG. 1, the overshoot reduction circuit 6 is connected to the input line of the common-mode potential VCMN of the current source control circuit 4, and has a function of reducing the overshoot of the common-mode potential VCMN. The overshoot reduction circuit 6 receives a control signal CONT2 to select whether or not to perform the overshoot reduction operation, and when selecting, based on the control signal CONT2, to perform the overshoot reduction operation, reduces the overshoot of the common-mode potential VCMN. By providing the overshoot reduction circuit 6, the driver circuit can be connected to a receiver circuit having a different power supply voltage or process breakdown voltage.

Specifically, the overshoot reduction circuit 6 includes a switch SW6 which is connected to both ends of the resistance element R1 provided between the output line of the common-mode potential VCMN of the output circuit 2 and the input line of the common-mode potential VCMN of the current source control circuit 4, and based on the control signal CONT2, sets whether or not to cause a short circuit in both ends of the resistance element R1. When the overshoot reduction circuit 6 selects, based on the control signal CONT2, to perform the overshoot reduction operation, the switch SW6 causes a short circuit in both ends of the resistance element R1. This short-circuit operation can temporarily increase a frequency characteristic of the current source control circuit 4, whereby the overshoot of the output voltage can be reduced or prevented.

The overshoot reduction circuit 6 will be implemented, for example, using the circuit configuration of FIG. 3. Specifically, in the configuration of FIG. 3, the control signal CONT2 may be used instead of the control signal CONT1. The switch is on when the control signal CONT2 is high, and off when the control signal CONT2 is low. In other words, the overshoot reduction operation is performed when the control signal CONT2 is high, and is not performed when the control signal CONT2 is low. The configuration of FIG. 3 can be used no matter whether the input voltage is low or high. Note that, for example, when the input voltage range is limited, the switch may include only PMOS transistors or only NMOS transistors.

In this embodiment, the overshoot reduction circuit 6 is provided which receives the control signal CONT2 to select whether or not to perform the overshoot reduction operation, and when selecting, based on the control signal CONT2, to perform the overshoot reduction operation, reduces the overshoot of the common-mode potential VCMN. As a result, the driver circuit can be connected to a receiver circuit having a different power supply voltage or process breakdown voltage.

Also, the overshoot reduction circuit 6, when selecting, based on the control signal CONT2, to perform the overshoot reduction operation, causes a short circuit in both ends of the resistance element R1 provided between the output line of the common-mode potential VCMN of the output circuit 2 and the input line of the common-mode potential VCMN of the current source control circuit 4. With this configuration, the frequency characteristic of the current source control circuit 4 can be temporarily increased, whereby the overshoot of the output voltage can be reduced. Also, the clamp voltage is not required, and such a considerably simple configuration can be used to reduce or prevent the overshoot of the output voltage of the driver circuit, resulting in a low-power, small-area, and low-cost driver circuit which can reduce the overshoot.

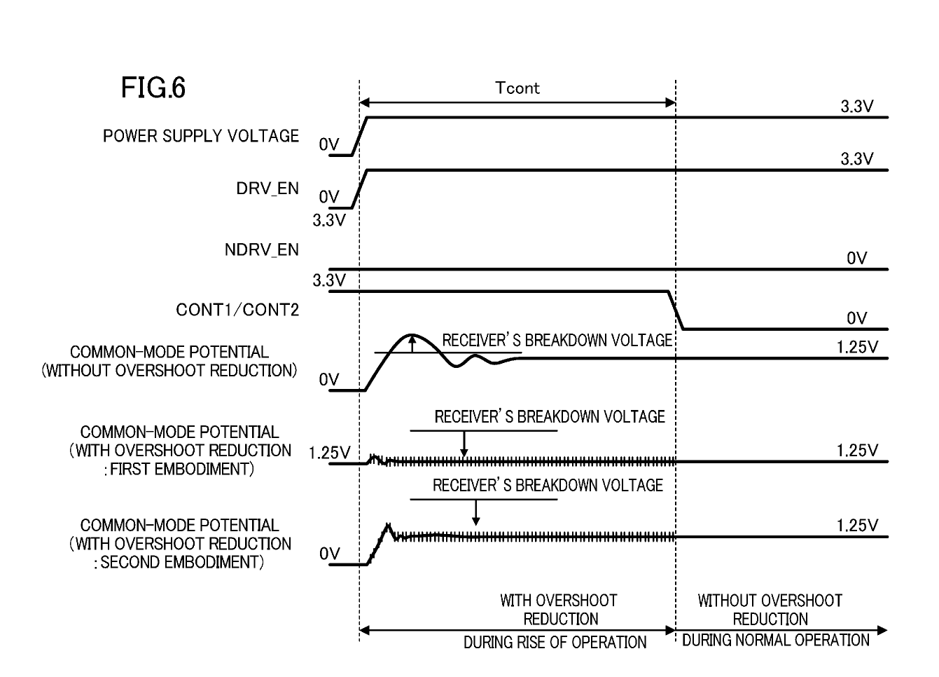

FIG. 5 is a circuit diagram showing another configuration of the driver circuit of this embodiment. In the configuration of FIG. 5, a second overshoot reduction circuit 7 is provided in addition to the overshoot reduction circuit 6. The second overshoot reduction circuit 7 includes a switch SW7 which is provided between the input line of the common-mode potential VCMN of the current source control circuit 4 and the capacitance element C1, and based on the control signal CONT2, sets whether or not to cut off the capacitance element C1 from the input line of the common-mode potential VCMN. When the second overshoot reduction circuit 7 selects, based on the control signal CONT2, to perform the overshoot reduction operation, the switch SW7 cuts off the capacitance element C1 from the input line of the common-mode potential VCMN. This cut-off operation further increases the frequency characteristic of the current source control circuit 4, whereby the overshoot of the output voltage can be further reduced.

In the driver circuits of the first and second embodiments, the timing of performing the overshoot reduction operation can be arbitrarily controlled based on the control signals CONT1 and CONT2. Note that the overshoot of the output voltage is highly likely to occur after the power supply is turned on. On the other hand, when the overshoot reduction operation is performed, the noise of the common-mode potential VCMN increases. Therefore, the control signals CONT1 and CONT2 are preferably set so that the overshoot reduction operation is selected to be performed during a predetermined period of time after the power supply of the driver circuit is turned on, and the overshoot reduction operation is selected not to be performed after the predetermined period of time has elapsed. By performing such a control, a reduction in an overshoot after the power supply is turned on, and lower-noise operation during normal operation, can both be achieved.

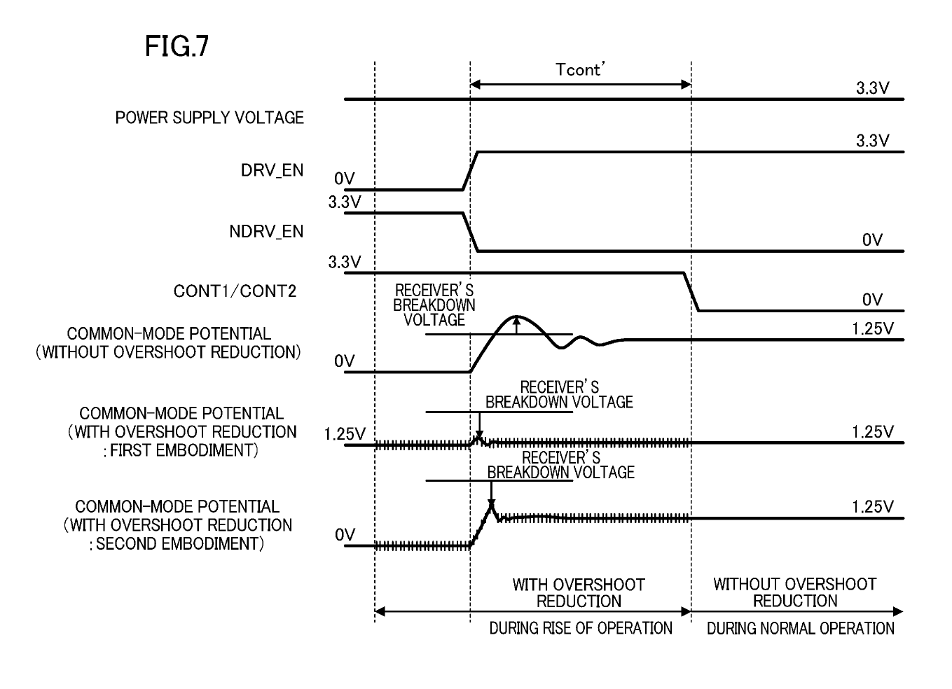

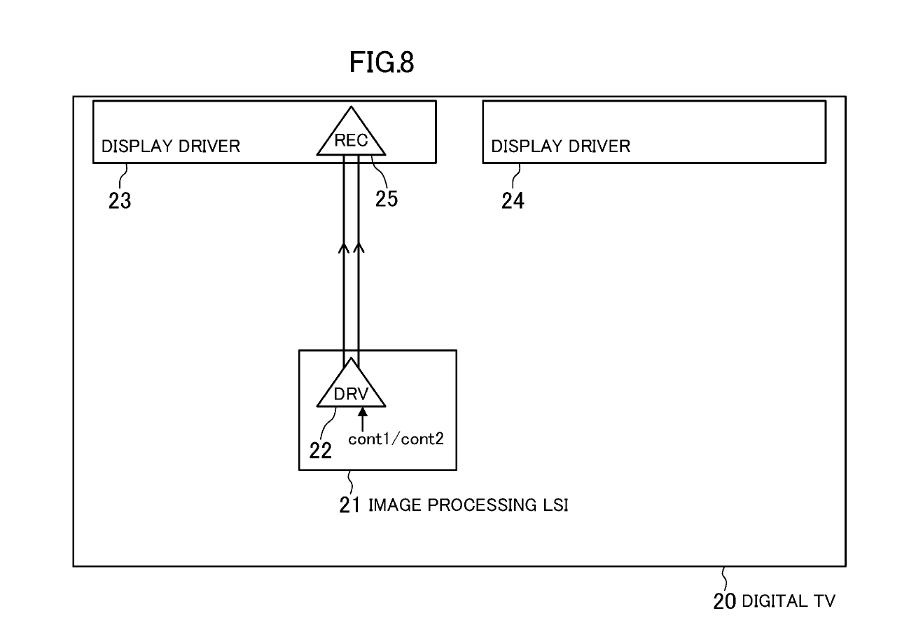

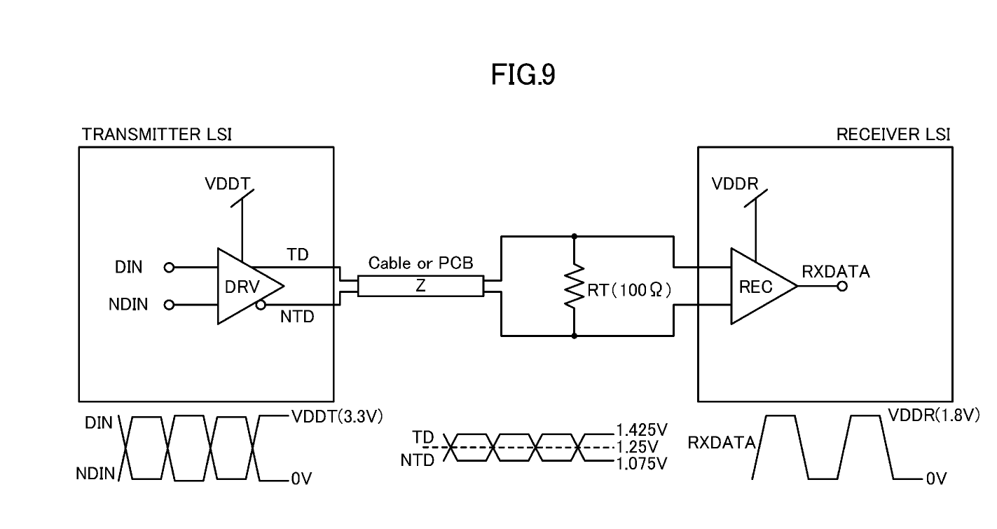

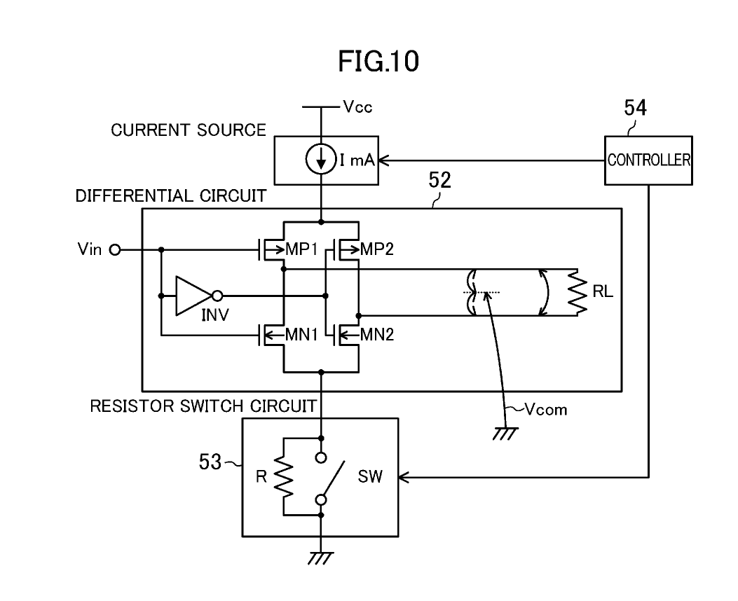

FIGS. 6 and 7 are timing diagrams showing an example of the control of the overshoot reduction operation. In FIGS. 6 and 7, the power supply voltage, the driver enable signal DRV_EN, the inverted version NDRV_EN of the signal DRV_EN, the control signals CONT1 and CONT2, a common-mode potential in the absence of the overshoot reduction operation, a common-mode potential in the presence of the overshoot reduction operation of the first embodiment, and a common-mode potential in the presence of the overshoot reduction operation of the second embodiment, are shown in this order from the top.

FIG. 6 shows a control sequence during the rise of the power supply. In the control of FIG. 6, the overshoot reduction operation is performed in connection with the power supply voltage. Specifically, the overshoot reduction operation is performed during a predetermined period of time Tcont (including a driver startup time) after the rise of the power supply voltage, and thereafter, the overshoot reduction operation is stopped.

FIG. 7 shows a control sequence where the power supply voltage is constant. In the control of FIG. 7, the overshoot reduction operation is performed in connection with the enable signal DRV_EN. Specifically, the power supply has already risen, and the on/off of the enable signal DRV_EN is controlled. The overshoot reduction operation is performed during a predetermined period of time Tcont′ after the rise of the enable signal DRV_EN, and thereafter, the overshoot reduction operation is stopped.

By the above control, an overshoot during the start of driver operation is reduced to a low level, and therefore, the common-mode potential VCMN does not exceed the receiver's breakdown voltage. Noise which would occur during the predetermined period of time Tcont or Tcont′ does not occur after the overshoot reduction operation is stopped. Thus, a reduction in an overshoot during the start of driver operation and lower-noise operation during normal operation can both be achieved.

Note that, in each of the above embodiments, constant current sources are provided on both sides of the power supply and the ground of an output circuit, and the currents of both of the constant current sources are adjusted by a current source control circuit. Alternatively, for example, a constant current source may be provided on only one side of the power supply or the ground, and the constant current source may be adjusted by a current source control circuit. Alternatively, a constant current source may be provided on only one side of the power supply or the ground of an output circuit, a resistance element may be provided on the other side instead of a constant current source. In this case, only the constant current source may be adjusted by a current source control circuit.

The first and second embodiments may be used in combination. For example, the overshoot reduction circuit 5 of FIG. 1 and the overshoot reduction circuit 6 of FIG. 4 may both be provided in a driver circuit.

Although the control signals CONT1 and CONT2 are input to an external pin provided in the overshoot reduction circuit in the above embodiments, the control signals CONT1 and CONT2 may be connected to a register which can be externally read and written by software and may be controlled by software, or may be signals fixed to the power supply or the ground by hardware.

FIG. 8 schematically shows an example configuration of a video system including the driver circuit of any of the above embodiments. In FIG. 8, a digital TV 20 which is an example of the video system includes an image processing LSI circuit 21 and display drivers 23 and 24. A driver circuit 22 of any of the embodiments is provided in the image processing LSI circuit 21, and is connected to a receiver circuit 25 in the display driver 23 via, for example, a cable or a PCB. The driver circuit 22 transmits an image signal to the receiver circuit 25. Note that, in some configuration of the digital TV 20, a timing controller IC is provided between the image processing LSI circuit 21 and the display driver 23. In this case, the driver circuit 22 is connected to a receiver circuit of the timing controller IC. Note that the system including the driver circuit of this embodiment is not limited to a digital TV.

The present disclosure can provide a driver circuit which can be connected to a receiver circuit having a different power supply voltage or process breakdown voltage, and therefore, can improve the versatility of a driver circuit in, for example, LVDS data transmission.

What is claimed is:

1. A driver circuit comprising:
an output circuit configured to receive a data signal, and output a differential signal based on the data signal;
a constant current source configured to supply a constant current to the output circuit, or extract a constant current from the output circuit;
a current source control circuit configured to receive a predetermined reference voltage and a common-mode potential of the differential signal, and control the constant current source so that the common-mode potential becomes equal to the predetermined reference potential; and
an overshoot reduction circuit connected to an input line of the common-mode potential of the current source control circuit, and having a function to reduce an overshoot of the common-mode potential,
wherein
the overshoot reduction circuit receives a control signal to select whether or not to perform the overshoot reduction operation, and when selecting, based on the control signal, to perform the overshoot reduction operation, reduces the overshoot of the common-mode potential.

2. The driver circuit of claim 1, wherein
the overshoot reduction circuit includes
a switch provided between an input line of the predetermined reference voltage and the input line of the common-mode potential of the current source control circuit, and configured to set, based on the control signal, whether or not to cause a short circuit in the two input lines, and
the switch causes a short circuit in the two input lines when the overshoot reduction circuit selects, based on the control signal, to perform the overshoot reduction operation.

3. The driver circuit of claim 1, further comprising:
a resistance element provided between an output line of the common-mode potential of the output circuit and the input line of the common-mode potential of the current source control circuit,
wherein
the overshoot reduction circuit includes
a switch connected to both ends of the resistance element, and configured to set, based on the control signal, whether or not to cause a short circuit in both ends of the resistance element, and
the switch causes a short circuit in both ends of the resistance element when the overshoot reduction circuit selects, based on the control signal, to perform the overshoot reduction operation.

4. The driver circuit of claim 2, wherein
the switch included in the overshoot reduction circuit includes a PMOS transistor and an NMOS transistor which are connected together in parallel.

5. The driver circuit of claim 2, wherein
the control signal is used to select to perform the overshoot reduction operation during a predetermined period of time after a power supply for the driver circuit is turned on, and to select not to perform the overshoot reduction operation after the predetermined period of time has elapsed.

6. The driver circuit of claim 3, wherein
the switch included in the overshoot reduction circuit includes a PMOS transistor and an NMOS transistor which are connected together in parallel.

7. The driver circuit of claim 3, wherein
the control signal is used to select to perform the overshoot reduction operation during a predetermined period of time after a power supply for the driver circuit is turned on, and to select not to perform the overshoot reduction operation after the predetermined period of time has elapsed.

8. A video system comprising:
an image processing LSI circuit including the driver circuit of claim 1; and
a display driver configured to receive an image signal which is transmitted from the image processing LSI via the driver circuit.
